(19) United States
(12) Patent Application Publication
(10) Pub. No.: US 2026/0173846 A1
(43) Pub. Date: Jun. 18, 2026

(54) SEMICONDUCTOR CHIP

(71) Applicant: Samsung Electronics Co., Ltd., Suwon-si (KR)

(72) Inventors: Kwangyeong Kim, Suwon-si (KR); Youngwoo Cho, Suwon-si (KR); Soongyu Hwang, Suwon-sI (KR)

(21) Appl. No.: 19/246,640

(22) Filed: Jun. 23, 2025

(30) Foreign Application Priority Data
Dec. 12, 2024 (KR) 10-2024-0185076

(51) Int. Cl. H01L 23/522; H01L 21/768; H01L 23/528

(52) U.S. Cl. CPC H10W 20/42; H10W 20/43; H10W 20/435; H10W 20/056; H10W 20/498

(57) ABSTRACT

A semiconductor chip includes a semiconductor substrate including an active surface and an inactive surface opposite to the active surface and an interconnection structure positioned on the active surface of the semiconductor substrate, the interconnection structure including a plurality of interconnection layers respectively including a plurality of interconnection lines and a plurality of interconnection vias and an interconnection insulating layer surrounding the plurality of interconnection layers, wherein the plurality of interconnection layers include an upper layer interconnection layer including a plurality of upper layer interconnection lines extending in a first horizontal direction and apart from each other in a second horizontal direction perpendicular to the first horizontal direction, and the upper layer interconnection layer further includes a plurality of upper layer interconnection vias including at least one upper layer asymmetric via.

### CROSS-REFERENCE TO RELATED APPLICATION(S)

This application is based on and claims priority under 35 USC § 119 to Korean Patent Application No. 10-2024-0185076, filed on Dec. 12, 2024, in the Korean Intellectual Property Office, the disclosure of which is incorporated by reference herein in its entirety.

### BACKGROUND

Semiconductor chips have continuously evolved, and the level of integration of semiconductor chips has increased. Such integration results in smaller interconnections within semiconductor chips, which may lead to increased resistance in interconnections. As interconnection resistance increases, signal transmission speeds may slow down, heat may be generated, and the performance and reliability of semiconductor chips may deteriorate. To reduce interconnection resistance, various research and technological developments have continuously been conducted.

### SUMMARY

The present disclosure provides a semiconductor chip with reduced resistance of an interconnection via of an interconnection structure.

However, the problems to be solved by the present disclosure are not limited to the problems mentioned above, and other problems not mentioned may be clearly understood by a person skilled in the art from the description below.

According to an aspect of the present disclosure, there is provided a semiconductor chip including a semiconductor substrate including an active surface and an inactive surface opposite to the active surface and an interconnection structure positioned on the active surface of the semiconductor substrate, the interconnection structure including a plurality of interconnection layers respectively including a plurality of interconnection lines and a plurality of interconnection vias and an interconnection insulating layer surrounding the plurality of interconnection layers, wherein the plurality of interconnection layers of the interconnection structure include an upper layer interconnection layer including a plurality of upper layer interconnection lines extending in a first horizontal direction and apart from each other in a second horizontal direction perpendicular to the first horizontal direction, and the upper layer interconnection layer further includes a plurality of upper layer interconnection vias including at least one upper layer asymmetric via in which slopes on two side surfaces opposite to each other in the second horizontal direction are different.

According to another aspect of the present disclosure, there is provided a semiconductor chip including a semiconductor substrate including an active surface and an inactive surface opposite to the active surface and an interconnection structure positioned on the active surface of the semiconductor substrate, the interconnection structure including a plurality of interconnection layers respectively including a plurality of interconnection lines and a plurality of interconnection vias and an interconnection insulating layer surrounding the plurality of interconnection layers, wherein the plurality of interconnection layers of the interconnection structure include a lower layer interconnection layer and an upper layer interconnection layer positioned on the lower layer interconnection layer, the lower layer interconnection layer includes a plurality of lower layer interconnection lines extending in a second horizontal direction and apart from each other in a first horizontal direction perpendicular to the second horizontal direction, the upper layer interconnection layer includes a plurality of upper layer interconnection lines extending in the first horizontal direction and apart from each other in the second horizontal direction and a plurality of upper layer interconnection vias connecting the plurality of upper layer interconnection lines to the plurality of lower layer interconnection lines, a width of the plurality of upper layer interconnection vias narrowing toward the plurality of lower layer interconnection lines, and the plurality of upper layer interconnection vias of the upper layer interconnection layer include at least one upper layer asymmetric via in which slopes of two side surfaces opposite to each other in the second horizontal direction are different.

According to another aspect of the present disclosure, there is provided a semiconductor chip including a semiconductor substrate including an active surface and an inactive surface opposite to the active surface and an interconnection structure positioned on the active surface of the semiconductor substrate, the interconnection structure including a plurality of interconnection layers respectively including a plurality of interconnection lines and a plurality of interconnection vias and an interconnection insulating layer surrounding the plurality of interconnection layers, wherein the plurality of interconnection layers of the interconnection structure include an upper layer interconnection layer including a plurality of upper layer interconnection lines extending in a first horizontal direction and apart from each other in a second horizontal direction perpendicular to the first horizontal direction, the upper layer interconnection layer further includes a plurality of upper interconnection vias including an upper layer asymmetric via in which slopes of two side surfaces opposite to each other in the second horizontal direction are different and a symmetric via in which slopes of two side surfaces opposite to each other in the second horizontal direction are the same, a number of the upper layer asymmetric vias is an even number, the upper layer asymmetric via includes a pair of upper layer asymmetric vias arranged in a straight line in the second horizontal direction, and respective high-slope side surfaces of the pair of upper layer asymmetric vias face each other.

### BRIEF DESCRIPTION OF THE DRAWINGS

Implementations are more clearly understood from the following detailed description taken in conjunction with the accompanying drawings in which:

FIG. 1 is a cross-sectional view schematically illustrating a semiconductor chip according to an implementation;

FIG. 2 is a plan view schematically illustrating a portion of an interconnection structure of a semiconductor chip according to an implementation;

FIG. 3 is a cross-sectional view schematically illustrating the semiconductor chip of FIG. 2 taken along line A3-A3′ of FIG. 2;

FIG. 4 is an enlarged view of portion EX4 of the semiconductor chip of FIG. 3;

FIG. 5 is a cross-sectional view schematically illustrating the semiconductor chip of FIG. 2 taken along line A5-A5′ of FIG. 2;

FIG. 6 is a cross-sectional view schematically illustrating the semiconductor chip of FIG. 2 taken along line A6-A6′ of FIG. 2;

FIG. 7 is a cross-sectional view schematically illustrating the semiconductor chip of FIG. 2 taken along line A7-A7′ of FIG. 2;

FIG. 8 is an enlarged view of a portion of a semiconductor chip according to an implementation;

FIGS. 9A to 9I are cross-sectional views illustrating a sequential process of manufacturing a semiconductor chip, according to an implementation; and

FIGS. 10 to 13 are plan views illustrating some of operations of manufacturing a semiconductor chip, according to an implementation.

### DETAILED DESCRIPTION

The implementations are provided to more completely describe the present disclosure to those skilled in the art to which the present disclosure pertains, and the following implementations may be modified in various other forms, and the scope of the present disclosure is not limited to the following implementations. Rather, these implementations are provided so that this disclosure is more faithful and complete, and fully conveys the spirit of the present disclosure to those skilled in the art.

Although terms, such as “first,” “second,” “third,” etc. are used throughout this specification to describe various components, parts, regions, layers and/or sections, it should be understood that such components, parts, regions, layers and/or sections are not limited by such terms. Unless the context indicates otherwise, these terms are merely naming rules used to distinguish one component, part, region, layer or section from another component, part, region, layer or section. Thus, a first component, part, region, layer or section discussed in one section of this specification may also be termed a second component, part, region, layer or section in another section of this specification or in claims without departing from the technical spirit of the present disclosure. In addition, in certain cases, different devices in the claims may be designated as “first,” “second,” etc., to be distinguished from each other although they are not described as “first” or “second” in the specification.

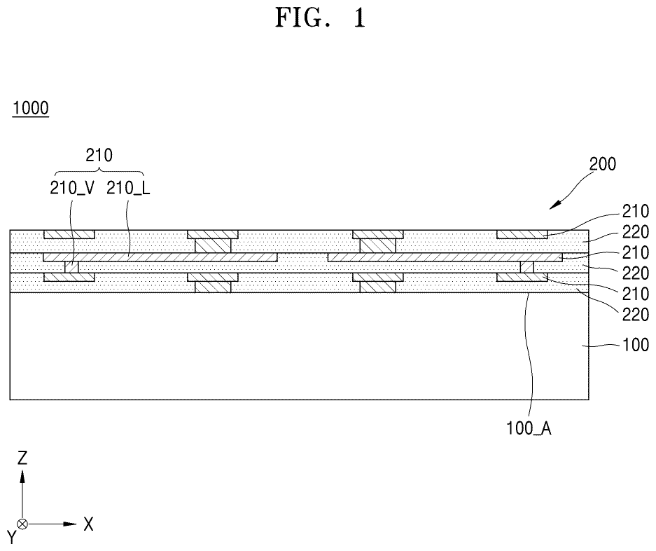

FIG. 1 is a cross-sectional view schematically illustrating a semiconductor chip 1000 according to an implementation.

Referring to FIG. 1, the semiconductor chip 1000 may include a semiconductor substrate 100 and an interconnection structure 200.

Herein, unless specifically defined otherwise, a direction parallel to an upper surface of the semiconductor substrate 100 is defined as a first horizontal direction (a Y direction), a direction perpendicular to the upper surface of the semiconductor substrate 100 is defined as a vertical direction (a Z direction), and a direction perpendicular to the first horizontal direction (the Y direction) and the vertical direction (the Z direction) is defined as a second horizontal direction (an X direction). The horizontal direction is defined as a direction that is a composite of the first horizontal direction (the Y direction) and the second horizontal direction (the X direction).

The semiconductor substrate 100 may include an active surface 100_A and an inactive surface opposite thereto. For example, the active surface 100_A of the semiconductor substrate 100 may be referred to as a front surface, and the inactive surface of the semiconductor substrate 100 may be referred to as a rear surface.

The semiconductor substrate 100 may include, for example, silicon (Si). Alternatively, the semiconductor substrate 100 may include a semiconductor element, such as germanium (Ge), or a compound semiconductor, such as silicon carbide (SiC), gallium arsenide (GaAs), indium arsenide (InAs), and indium phosphide (InP).

The semiconductor substrate 100 may include a conductive region, for example, a well doped with impurities or a structure doped with impurities. A semiconductor device layer including individual devices may be provided on the active surface 100_A of the semiconductor substrate 100. The individual devices may include, for example, transistors. The individual devices may include microelectronic devices, such as metal-oxide-semiconductor field effect transistors (MOSFETs), system large scale integration (LSI), image sensors, such as complementary metal oxide semiconductor imaging sensors (CIS), micro-electro-mechanical systems (MEMS), active devices, passive devices, etc.

For example, depending on the individual devices positioned on the active surface 100_A of the semiconductor substrate 100, the semiconductor chip 1000 may be a memory chip or a logic chip. The memory chip may be a volatile memory semiconductor chip, such as dynamic random access memory (DRAM) and static random access memory (SRAM) or a nonvolatile memory semiconductor chip, such as phase-change random access memory (PRAM), magnetoresistive random access memory (MRAM), ferroelectric random access memory (FeRAM), and resistive random access memory (RRAM). The logic chip may be a central processing unit (CPU) chip, a graphics processing unit (GPU) chip, an application processor (AP) chip, or an application specific integrated circuit (ASIC) chip.

The interconnection structure 200 may be positioned on the active surface 100_A of the semiconductor substrate 100. The interconnection structure 200 may include a plurality of interconnection layers 210 and an interconnection insulating layer 220 covering the plurality of interconnection layers 210. In some implementations, the interconnection structure 200 may include a plurality of interconnection insulating layers 220 correspondingly covering the plurality of interconnection layers 210.

In some implementations, an etch stop layer and an interconnection protective layer may be located between an upper surface of each of a plurality of interconnection lines 210_L of the plurality of interconnection layers 210 and the interconnection insulating layer 220.

Each of the plurality of interconnection layers 210 may include a plurality of interconnection lines 210_L extending in a horizontal direction and a plurality of interconnection vias 210_V extending in a vertical direction (the Z direction) from the plurality of interconnection lines 210_L. Vertical levels of the plurality of interconnection lines 210_L of the plurality of interconnection layers 210 may be different from each other. The plurality of interconnection vias 210_V of each of the plurality of interconnection layers 210 may electrically connect the plurality of interconnection lines 210_L in different interconnection layers 210 through the interconnection insulating layer 220.

In some implementations, the plurality of interconnection lines 210_L and the plurality of interconnection vias 210_V of each of a plurality of interconnection layers 210 may be manufactured at once using a dual damascene process, so that the plurality of interconnection lines 210_L and the plurality of interconnection vias 210_V may be integrated without any boundary surface.

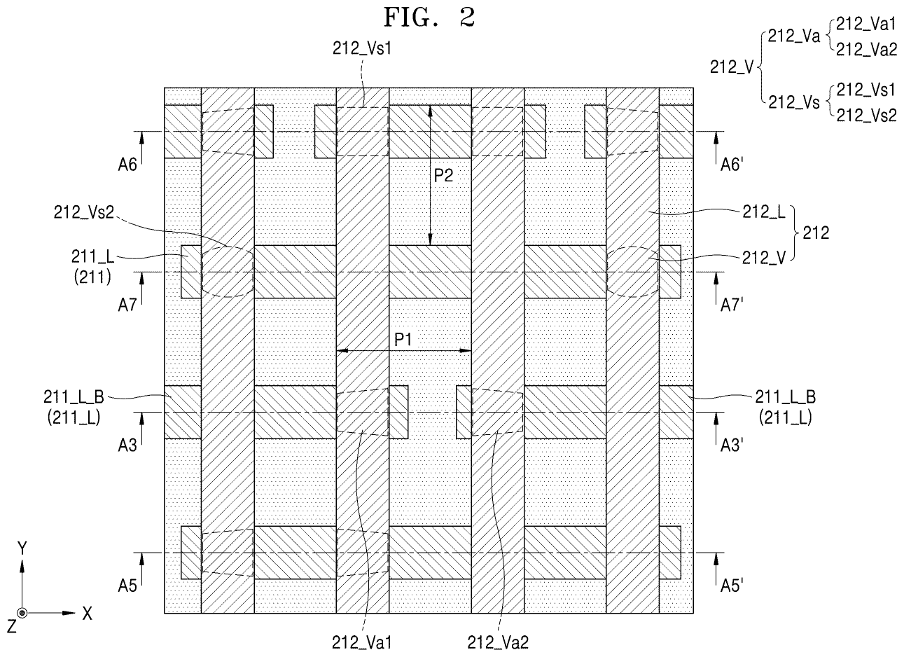

In some implementations, the plurality of interconnection layers 210 may include a conductive material, for example, copper (Cu), aluminum (Al), silver (Ag), tin (Sn), gold (Au), nickel (Ni), lead (Pb), titanium (Ti), manganese (Mn), cobalt (Co), tungsten (W) or alloys thereof. The plurality of interconnection layers 210 are described below in detail with reference to FIGS. 2 to 8.

The interconnection insulating layer 220 may insulate the plurality of interconnection lines 210_L positioned on different interconnection layers 210. In FIG. 1, the interconnection insulating layers 220 covering each of the plurality of interconnection layers 210 are illustrated as forming one body without a boundary surface, but without being limited thereto, an interface may exist between the interconnection insulating layers 220 covering each of the plurality of interconnection layers 210.

For example, the interconnection insulating layer 220 may include silicon oxide, silicon oxynitride, an insulating material having a lower dielectric constant than silicon oxide, or combinations thereof.

In some implementations, the interconnection structure 200 may further include a bump pad. The bump pad may be a portion of the uppermost interconnection layer 210 among the plurality of interconnection layers 210. The bump pad may be an externally exposed portion of the plurality of interconnection lines 210_L of the uppermost interconnection layer 210.

In some implementations, external connection terminals may be attached to the bump pad of the interconnection structure 200. The external connection terminals may include at least one of a conductive material, such as solder, tin (Sn), silver (Ag), copper (Cu), and aluminum (Al).

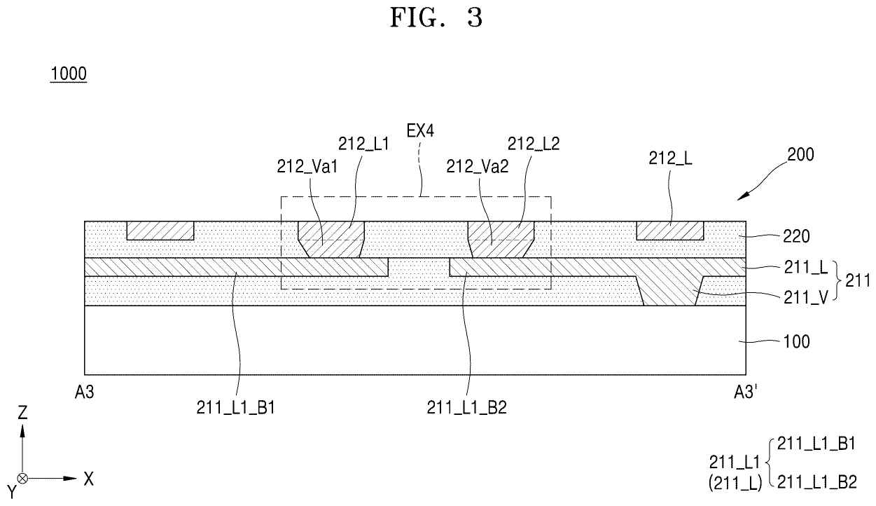

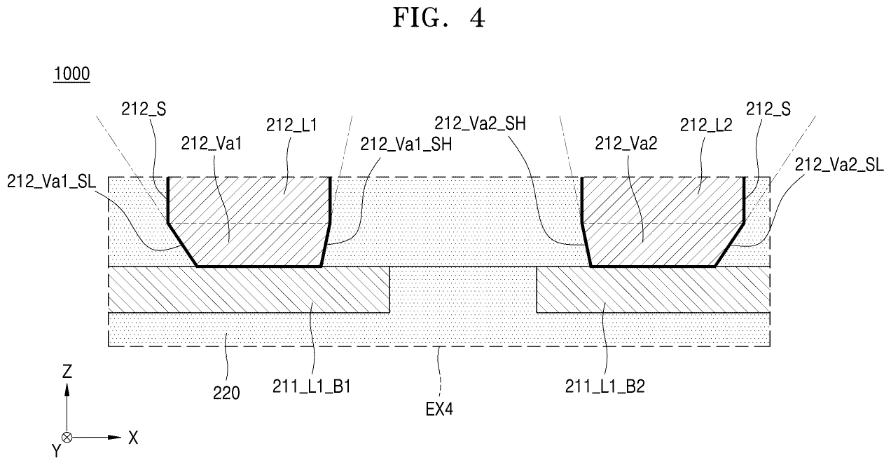

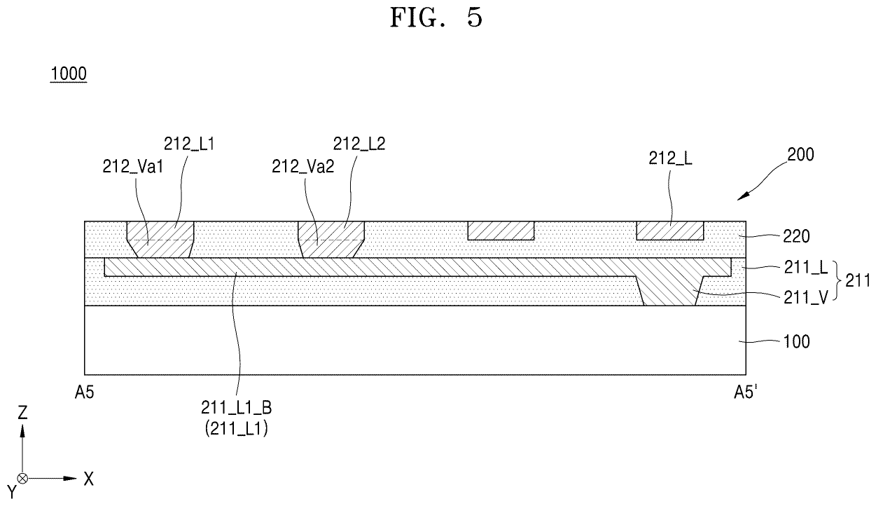

FIG. 2 is a plan view schematically illustrating a portion of the interconnection structure 200 of the semiconductor chip 1000 according to an implementation. FIG. 3 is a cross-sectional view schematically illustrating the semiconductor chip 1000 of FIG. 2 taken along line A3-A3′ of FIG. 2. FIG. 4 is an enlarged view of portion EX4 of the semiconductor chip 1000 of FIG. 3. FIG. 5 is a cross-sectional view schematically illustrating the semiconductor chip 1000 of FIG. 2 taken along line A5-A5′ of FIG. 2.

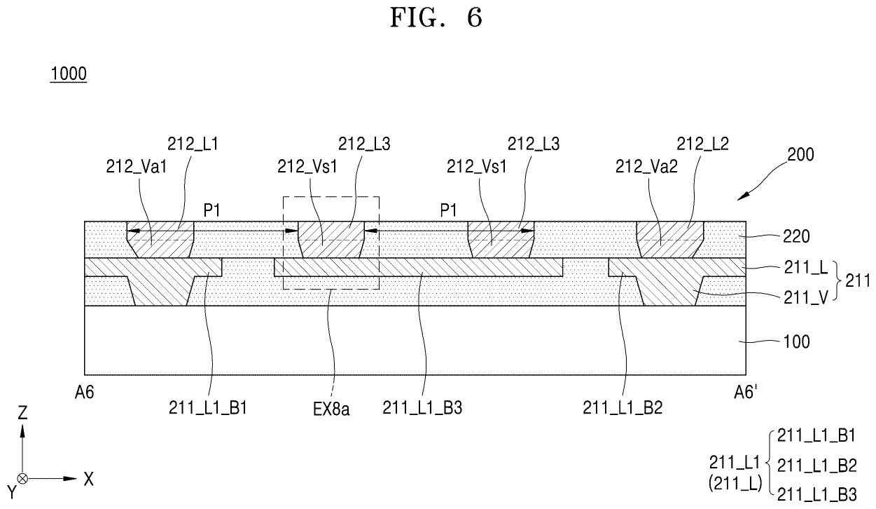

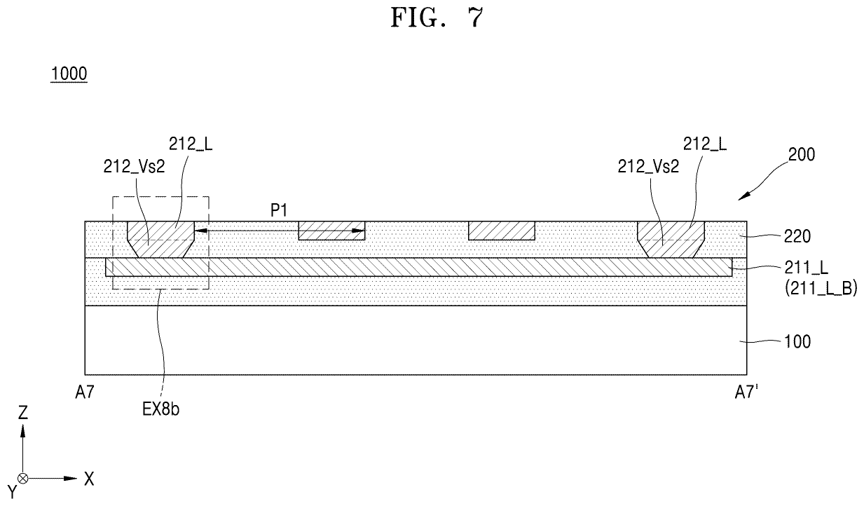

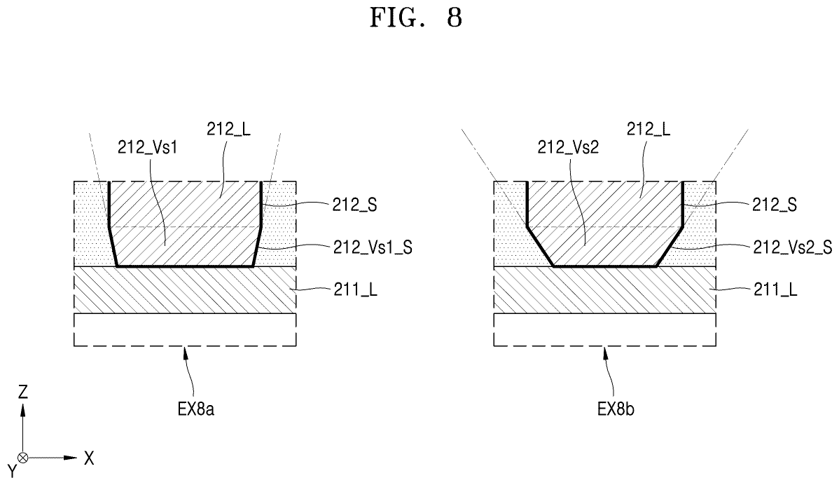

FIG. 6 is a cross-sectional view schematically illustrating the semiconductor chip 1000 of FIG. 2 taken along line A6-A6′ of FIG. 2. FIG. 7 is a cross-sectional view schematically illustrating the semiconductor chip 1000 of FIG. 2 taken along line A7-A7′ of FIG. 2. FIG. 8 is an enlarged view of a portion of the semiconductor chip 1000 according to an implementation.

Referring to FIGS. 2 to 8, the plurality of interconnection layers 210 of the interconnection structure 200 may include a lower layer interconnection layer 211 and an upper layer interconnection layer 212 positioned on the lower layer interconnection layer 211. For example, the upper layer interconnection layer 212 may be an interconnection layer 210 positioned directly above the lower layer interconnection layer 211.

Through FIG. 2, a schematic layout of the upper layer interconnection layer 212 and the lower layer interconnection layer 211 is described. The upper layer interconnection layer 212 and the lower layer interconnection layer 211 only indicate relative positions of two adjacent interconnection layers 210 and do not indicate the interconnection layer 210 positioned in a certain layer. For example, in FIG. 3, the lower layer interconnection layer 211 appears as a first-layer interconnection layer positioned on the semiconductor substrate 100 and the upper layer interconnection layer 212 appears as a second-layer interconnection layer, but the positions of the lower layer interconnection layer 211 and the upper layer interconnection layer 212 are not limited thereto.

The lower layer interconnection layer 211 may include a plurality of lower layer interconnection lines 211_L and a plurality of lower layer interconnection vias 211_V. The plurality of lower layer interconnection lines 211_L may extend in the second horizontal direction (the X direction) and be apart from each other in the first horizontal direction (the Y direction). For example, a distance between each of the plurality of lower layer interconnection lines 211_L and the adjacent lower layer interconnection line 211_L may be a second pitch P2.

Each of the plurality of lower layer interconnection vias 211_V may extend downward in the vertical direction (the Z direction) from lower surfaces of the plurality of lower layer interconnection lines 211_L. For example, the plurality of lower layer interconnection vias 211_V may be electrically connected to a conductive region of the semiconductor substrate 100.

In some implementations, an etch stop layer may be positioned on an upper surface of each of the plurality of lower layer interconnection lines 211_L. The etch stop layer may be located between the interconnection insulating layer 220 and the upper surfaces of the plurality of lower layer interconnection lines 211_L. In some implementations, an interconnection protective layer may be located between the etch stop layer and the plurality of lower layer interconnection lines 211_L.

The upper layer interconnection layer 212 may include a plurality of upper layer interconnection lines 212_L and a plurality of upper layer interconnection vias 212_V. The plurality of upper layer interconnection lines 212_L may extend in the first horizontal direction (the Y direction) and be apart from each other in the second horizontal direction (the X direction). For example, a distance between each of the plurality of upper layer interconnection lines 212_L and the adjacent upper layer interconnection line 212_L may be a first pitch P1.

For example, an extension direction of each of the plurality of upper layer interconnection lines 212_L of the upper layer interconnection layer 212 may be orthogonal to an extension direction of each of the plurality of lower layer interconnection lines 211_L of the lower layer interconnection layer 211.

However, without being limited thereto, depending on the design of the interconnection structure 200, the plurality of lower layer interconnection lines 211_L may include a first lower layer interconnection pattern extending in the first horizontal direction (the Y direction) and a second lower layer interconnection pattern extending in the second horizontal direction (the X direction), and the plurality of upper layer interconnection lines 212_L may include a first upper layer interconnection pattern extending in the first horizontal direction (the Y direction) and a second upper layer interconnection pattern extending in the second horizontal direction (the X direction).

In some implementations, the plurality of lower layer interconnection lines 211_L may include a plurality of lower layer interconnection blocks 211_L_B, respectively. The plurality of lower layer interconnection blocks 211_L_B included in the same lower layer interconnection line 211_L may extend in the second horizontal direction (the X direction) and may be apart from each other in the second horizontal direction (the X direction). For example, the plurality of lower layer interconnection blocks 211_L_B included in the same lower layer interconnection line 211_L may be arranged in a row in the second horizontal direction (the X direction).

In some implementations, the plurality of upper layer interconnection lines 212_L may include a plurality of upper layer interconnection blocks, respectively, like the plurality of lower layer interconnection lines 211_L. The plurality of upper layer interconnection blocks included in the same upper layer interconnection line 212_L may extend in the first horizontal direction (the Y direction) and may be apart from each other in the first horizontal direction (the Y direction). For example, the plurality of upper layer interconnection blocks included in the same upper layer interconnection line 212_L may be arranged in a row in the first horizontal direction (the Y direction).

For example, the interconnection pattern of the interconnection structure 200 may be diversified through the plurality of lower layer interconnection blocks 211_L_B of the plurality of lower layer interconnection lines 211_L and the plurality of upper layer interconnection blocks of the plurality of upper layer interconnection lines 212_L.

The plurality of upper layer interconnection vias 212_V may extend downward in the vertical direction (the Z direction) from the respective lower surfaces of the plurality of upper layer interconnection lines 212_L. In some implementations, a width of each of the plurality of upper layer interconnection vias 212_V may decrease away from the plurality of upper layer interconnection lines 212_L.

The plurality of upper layer interconnection vias 212_V may be electrically connected to the plurality of lower layer interconnection lines 211_L, respectively. For example, the upper surface of each of the plurality of upper layer interconnection vias 212_V may be in contact with one of the plurality of upper layer interconnection lines 212_L, and the lower surface of each of the plurality of upper layer interconnection vias 212_V may be in contact with one of the plurality of lower layer interconnection lines 211_L.

For example, there is no etch stop layer between the plurality of lower layer interconnection lines 211_L and the plurality of upper layer interconnection vias 212_V, and thus, the plurality of lower layer interconnection lines 211_L may be in direct contact with the plurality of upper layer interconnection vias 212_V. For example, the plurality of upper layer interconnection vias 212_V may be positioned at points in which the plurality of upper layer interconnection lines 212_L intersect the plurality of lower layer interconnection lines 211_L.

The plurality of upper layer interconnection vias 212_V may include at least one upper layer asymmetric via 212_Va and at least one symmetric via 212_Vs. For example, the plurality of upper layer interconnection vias 212_V may include an even number of upper layer asymmetric vias 212_Va.

Opposite side surfaces of the upper layer asymmetric via 212_Va, which are opposite to each other in a direction (e.g., the second horizontal direction (the X direction)) perpendicular to the extension direction of each of the plurality of upper layer interconnection lines 212_L, may have different slopes. Among the opposite side surfaces of the upper layer asymmetric via 212_Va having different slopes, the side surface having a relatively large slope may be referred to as a high-slope side surface and the side surface having a relatively small slope may be referred to as a low-slope side surface.

Opposite side surfaces of the symmetric via 212_Vs, which are opposite to each other in a direction (e.g., the second horizontal direction (the X direction)) perpendicular to the extension direction of each of the plurality of upper layer interconnection lines 212_L, may have the same slope. Herein, the side surface of a symmetric via 212_Vs refers to one of opposite side surfaces that are opposite to each other in a direction (e.g., the second horizontal direction (the X direction)) perpendicular to the direction in which each of the plurality of upper layer interconnection lines 212_L extends.

For example, the symmetric via 212_Vs may include a low-slope symmetric via 212_Vs2 having a relatively small side slope and a high-slope symmetric via 212_Vs1 having a relatively large side slope.

An implementation of forming a pair of upper layer asymmetric vias in two upper layer interconnection lines 212_L adjacent to each other among the plurality of upper layer interconnection lines 212_L is described with reference to FIGS. 3 to 5.

Referring to FIGS. 3 and 4, the plurality of upper layer interconnection vias 212_V may include a first upper layer asymmetric via 212_Va1 and a second upper layer asymmetric via 212_Va2. The first upper layer asymmetric via 212_Va1 and the second upper layer asymmetric via 212_Va2 may be arranged in a straight line in the second horizontal direction (the X direction). For example, the first upper layer asymmetric via 212_Va1 and the second upper layer asymmetric via 212_Va2 may be collectively referred to as a pair of upper layer asymmetric vias. For example, the first upper layer asymmetric via 212_Va1 and the second upper layer asymmetric via 212_Va2 may be positioned on the same lower layer interconnection line 211_L.

The first upper layer asymmetric via 212_Va1 may include a first low-slope side surface 212_Va1_SL and a first high-slope side surface 212_Va1_SH opposite to the first low-slope side surface 212_Va1_SL in the second horizontal direction (the X direction).

The second upper layer asymmetric via 212_Va2 may include a second low-slope side surface 212_Va2_SL and a second high-slope side surface 212_Va_SH opposite to the second low-slope side surface 212_Va2_SL in the second horizontal direction (the X direction).

The first high-slope side surface 212_Va1_SH of the first upper layer asymmetric via 212_Va1 may face the second high-slope side surface 212_Va2_SH of the second upper layer asymmetric via 212_Va2. For example, a distance between the first low-slope side surface 212_Va1_SL of the first upper layer asymmetric via 212_Va1 and the second high-slope side surface 212_Va2_SH of the second upper layer asymmetric via 212_Va2 may be greater than a distance between the first high-slope side surface 212_Va1_SH of the first upper layer asymmetric via 212_Va1 and the second high-slope side surface 212_Va2_SH of the second upper layer asymmetric via 212_Va2. For example, the first upper layer asymmetric via 212_Va1 and the second upper layer asymmetric via 212_Va2 may be arranged symmetrically with respect to a Y-Z plane.

In some implementations, the first upper layer asymmetric via 212_Va1 may be connected to a first upper layer interconnection line 212_L1, and the second upper layer asymmetric via 212_Va2 may be connected to a second upper layer interconnection line 212_L2. The first upper layer interconnection line 212_L1 may be adjacent to the second upper layer interconnection line 212_L2. For example, the first upper layer interconnection line 212_L1 may be one of the upper layer interconnection lines 212_L positioned on opposite sides of the second upper layer interconnection line 212_L2 among the plurality of upper layer interconnection lines 212_L. For example, a separation distance between the first upper layer asymmetric via 212_Va1 and the second upper layer asymmetric via 212_Va2 may be the first pitch P1.

In some implementations, the upper layer interconnection layer 212 may further include an upper layer seed layer 212_S. For example, the upper layer seed layer 212_S may surround an outer surface excluding upper surfaces of the plurality of upper layer interconnection lines 212_L and the plurality of upper layer interconnection vias 212_V. The upper layer seed layer 212_S may be conformally formed on the side surface of each of the plurality of upper layer interconnection lines 212_L and the side surface and lower surface of each of the plurality of upper layer interconnection vias 212_V. However, the upper layer seed layer 212_S may be formed integrally with each of the plurality of upper layer interconnection lines 212_L and each of the plurality of upper layer interconnection vias 212_V, without a boundary surface.

In some implementations, the upper layer seed layer 212_S may include a plurality of layers of different constituent materials. For example, the upper layer seed layer 212_S may include a barrier metal layer that prevents a conductive material from penetrating into the interconnection insulating layer 220 and a liner layer positioned on the barrier metal layer. For example, the barrier metal layer may include ruthenium (Ru), tantalum nitride (TaN), tantalum (Ta), or compounds thereof, and the liner layer may include cobalt (Co), ruthenium (Ru), manganese (Mn), or compounds thereof.

Referring to FIG. 3, the plurality of lower layer interconnection lines 211_L may include a first lower layer interconnection line 211_L1 including a first lower layer interconnection block 211_L1_B1 and a second lower layer interconnection block 211_L1_B2. The first lower layer interconnection block 211_L1_B1 may be adjacent to the second lower layer interconnection block 211_L1_B2. The interconnection insulating layer 220 may be located between the first lower layer interconnection block 211_L1_B1 and the second lower layer interconnection block 211_L1_B2. The first upper layer asymmetric via 212_Va1 may contact the first lower layer interconnection block 211_L_B1, and the second upper layer asymmetric via 212_Va2 may contact the second lower layer interconnection block 211_L1_B2.

For example, the first upper layer interconnection line 212_L1 and the first lower layer interconnection block 211_L1_B1 may be electrically connected through the first upper layer asymmetric via 212_Va1, and the second upper layer interconnection line 212_L2 and the second lower layer interconnection block 211_L1_B2 may be electrically connected through the second upper layer asymmetric via 212_Va2.

Referring to FIG. 5, the first upper layer asymmetric via 212_Va1 and the second upper layer asymmetric via 212_Va2 may be connected to one lower layer interconnection block 211_L1_B among the plurality of lower layer interconnection blocks 211_L1_B of the first lower layer interconnection line 211_L1.

The first upper layer interconnection line 212_L1 and the second upper layer interconnection line 212_L2 may be electrically connected through the first upper layer asymmetric via 212_Va1, one lower layer interconnection block 211_L1_B, and the second upper layer asymmetric via 212_Va2.

Referring to FIG. 6, an implementation in which a pair of the upper layer asymmetric via and the high-slope symmetric via 212_Vs1 are formed on at least three upper layer interconnection lines 212_L that are sequentially arranged among the plurality of upper layer interconnection lines 212_L is described.

Referring to FIG. 6, the plurality of upper layer interconnection vias 212_V may include the first upper layer asymmetric via 212_Va1, the second upper layer asymmetric via 212_Va2, and the high-slope symmetric via 212_Vs1.

Opposite side surfaces of the high-slope symmetric via 212_Vs1 that are opposite in the direction (e.g., the second horizontal direction (the X direction)) perpendicular to the direction in which the upper layer interconnection line 212_L extends may have the same slope. In some implementations, the slope of the side surface of the high-slope symmetric via 212_Vs1 may be substantially the same as the slope of the first high-slope side surface 212_Va1_SH of the first upper layer asymmetric via 212_Va1. The slope of the side surface of the high-slope symmetric via 212_Vs1 may be greater than the slope of the first low-slope side surface 212_Va1_SL of the first upper layer asymmetric via 212_Va1.

The first upper layer asymmetric via 212_Va1, the second upper layer asymmetric via 212_Va2, and the high-slope symmetric via 212_Vs1 may be arranged in a row in the second horizontal direction (the X direction). The high-slope symmetric via 212_Vs1 may be located between the first upper layer asymmetric via 212_Va1 and the second upper layer asymmetric via 212_Va2. The first high-slope side surface 212_Va1_SH of the first upper layer asymmetric via 212_Va1 may face the side surface of the high-slope symmetric via 212_Vs1, and the second high-slope side surface 212_Va2_SH of the second upper layer asymmetric via 212_Va2 may face the side surface of the high-slope symmetric via 212_Vs1. For example, the high-slope symmetric via 212_Vs1 may be the upper layer interconnection via 212_V located between a pair of asymmetric vias.

The plurality of upper layer interconnection lines 212_L may include the first upper layer interconnection line 212_L1, the second upper layer interconnection line 212_L2, and a third upper layer interconnection line 212_L3, which are arranged sequentially. The first upper layer interconnection line 212_L1 may be connected to the first upper layer asymmetric via 212_Va1, the second upper layer interconnection line 212_L2 may be connected to the second upper layer asymmetric via 212_Va2, and the third upper layer interconnection line 212_L3 may be connected to the high-slope symmetric via 212_Vs1.

The third upper layer interconnection line 212_L3 may be located between the first upper layer interconnection line 212_L1 and the second upper layer interconnection line 212_L2. Each of the upper layer interconnection lines 212_L located between the first upper layer interconnection line 212_L1 and the second upper layer interconnection line 212_L2 may be referred to as the third upper layer interconnection line 212_L3. That is, the number of third upper layer interconnection lines 212_L3 may vary depending on a distance between the first upper layer interconnection line 212_L1 and the second upper layer interconnection line 212_L2.

For example, as illustrated in FIG. 6, when the distance between the first upper layer interconnection line 212_L1 and the second upper layer interconnection line 212_L2 is three times the first pitch P1, two third upper layer interconnection lines 212_L3 may be located between the first upper layer interconnection line 212_L1 and the second upper layer interconnection line 212_L2.

In some implementations, the number of high-slope symmetric vias 212_Vs1 located between the first upper layer asymmetric via 212_Va1 and the second upper layer asymmetric via 212_Va2 may be equal to the number of third upper layer interconnection lines 212_L 3. For example, the high-slope symmetric via 212_Vs1 may be positioned in each of the third upper layer interconnection lines 212_L3 located between the first upper layer interconnection line 212_L1 and the second upper layer interconnection line 212_L2.

The first upper layer asymmetric via 212_Va1, the second upper layer asymmetric via 212_Va2, and the high-slope symmetric via 212_Vs1 may be positioned on the first lower layer interconnection line 211_L1 of the plurality of lower layer interconnection lines 211_L.

As illustrated in FIG. 6, the first lower layer interconnection line 211_L1 may include a first lower layer interconnection block 211_L1_B1, a second lower layer interconnection block 211_L1_B2, and a third lower layer interconnection block 211_L1_B3 apart from each other in the second horizontal direction (the X direction).

The first lower layer interconnection block 211_L1_B1, the second lower layer interconnection block 211_L1_B2, and the third lower layer interconnection block 211_L1_B 3 may be adjacent to each other, and the third lower layer interconnection block 211_L1_B3 may be located between the first lower layer interconnection block 211_L1_B1 and the second lower layer interconnection block 211_L1_B2. For example, the first lower layer interconnection block 211_L1_B1 may be adjacent to the third lower layer interconnection block 211_L1_B3, and the second lower layer interconnection block 211_L1_B2 may be adjacent to the third lower layer interconnection block 211_L1_B3.

The first lower layer interconnection block 211_L1_B1 may be in contact with the first upper layer asymmetric via 212_Va1, the second lower layer interconnection block 211_L1_B2 may be in contact with the second upper layer asymmetric via 212_Va2, and the third lower layer interconnection block 211_L1_B3 may be in contact with the high-slope symmetric via 212_Vs1. For example, the first lower layer interconnection block 211_L1_B1, the third lower layer interconnection block 211_L1_B 3, and the second lower layer interconnection block 211_L1_B2 may be insulated from each other with the interconnection insulating layer 220 therebetween.

Referring to FIG. 7, the plurality of upper layer interconnection vias 212_V of the upper layer interconnection layer 212 may include low-slope symmetric vias 212_Vs2.

Opposite side surfaces of the low-slope symmetric via 212_Vs2, which are opposite to each other in a direction (e.g., the second horizontal direction (the X direction)) perpendicular to the direction in which the plurality of upper layer interconnection lines 212_L extend may have the same slope. In some implementations, the slope of the side surface of the low-slope symmetric via 212_Vs2 may be substantially the same as the slope of the first low-slope side surface 212_Va1_SL of the first upper layer asymmetric via 212_Va1.

In some implementations, when a distance from the upper layer interconnection via 212_V is positioned in a straight line with the low-slope symmetric via 212_Vs2 in the second horizontal direction (the X direction) and is closest to the low-slope symmetric via 212_Vs2 to the low-slope symmetric via 212_Vs2 is a first distance, the first distance may be greater than the first pitch P1. For example, within a distance apart by the first pitch P1 in the second horizontal direction (the X direction) of the low-slope symmetric via 212_Vs2, the upper layer interconnection via 212_V may not be positioned or another low-slope symmetric via 212_Vs2 may be positioned.

In some implementations, the low-slope symmetric via 212_Vs2 may not be located between the first upper layer asymmetric via 212_Va1 and the second upper layer asymmetric via 212_Va2 or may not be positioned in a straight line with the first upper layer asymmetric via 212_Va1 and the second upper layer asymmetric via 212_Va2.

FIG. 8 is a schematic enlarged view of portion Ex8a of FIG. 6 of the semiconductor chip 1000 of FIG. 6 and a schematic enlarged view of portion Ex8b of FIG. 7 of the semiconductor chip 1000 of FIG. 7. Referring to FIG. 8 together with FIGS. 6 and 7, the high-slope symmetric via 212_Vs1 and a low-slope symmetric via 212_Vs2 are compared.

The slope of the side surface 212_Vs1_S of the high-slope symmetric via 212_Vs1 may be greater than the slope of the side surface 212_Vs2_S of the low-slope symmetric via 212_Vs2. For example, the slope of the side surface 212_Vs1_S of the high-slope symmetric via 212_Vs1 may be the same as the slope of the high-slope side surface among the side surfaces of the upper layer asymmetric via (212_Va, see FIG. 2), and the slope of the side surface 212_Vs2_S of the low-slope symmetric via 212_Vs2 may be the same as the slope of the low-slope side surface among the side surfaces of the upper layer asymmetric via.

In some implementations, within a distance from the high-slope symmetric via 212_Vs1 apart by the first pitch P1 in the second horizontal direction (the X direction), at least two of another high-slope symmetric via 212_Vs1, the first upper layer asymmetric via 212_Va1, and the second upper layer asymmetric via 212_Va2 may be positioned. In comparison, within a distance from the low-slope symmetric via 212_Vs2 apart by the first pitch P1 in the second horizontal direction (the X direction), the upper layer interconnection via 212_V may not be positioned or another low-slope symmetric via 212_Vs2 may be positioned.

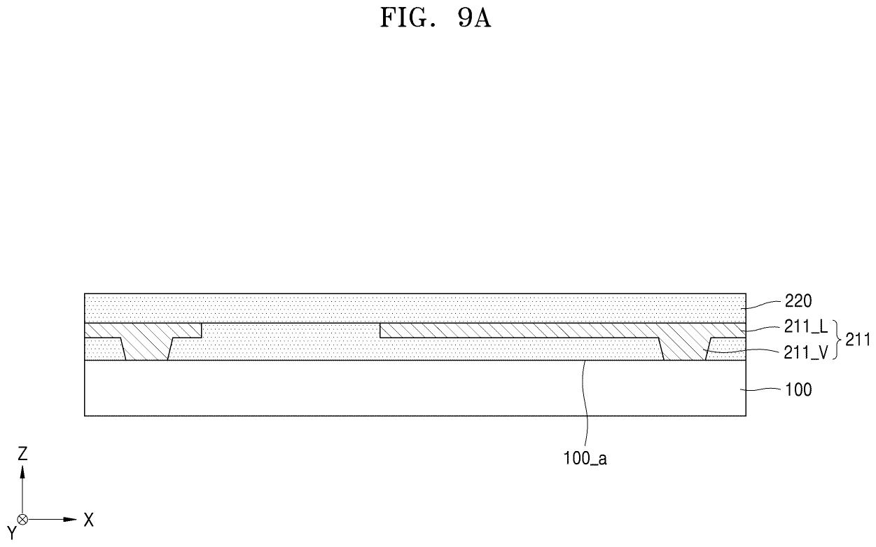

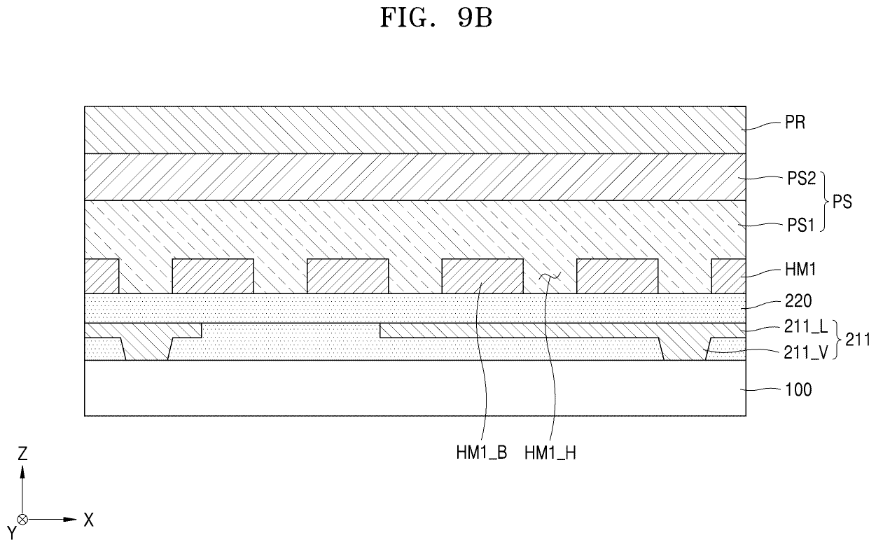

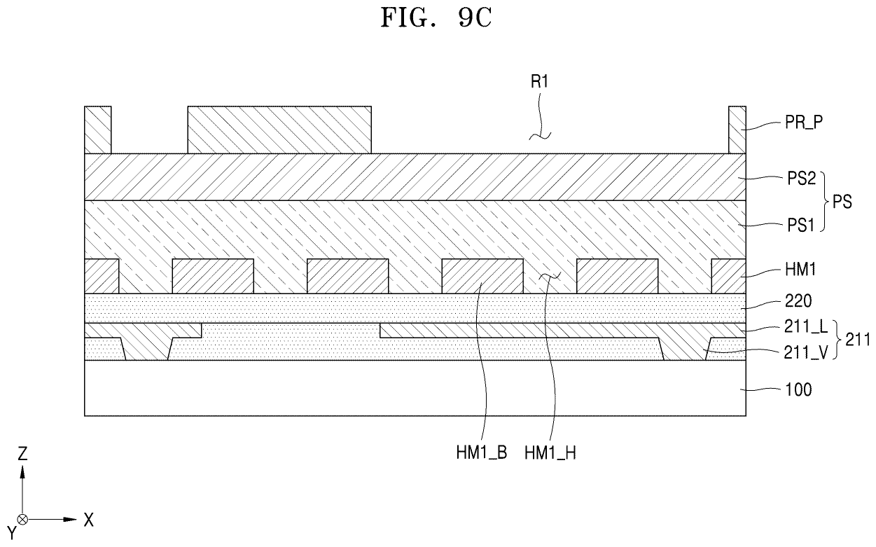

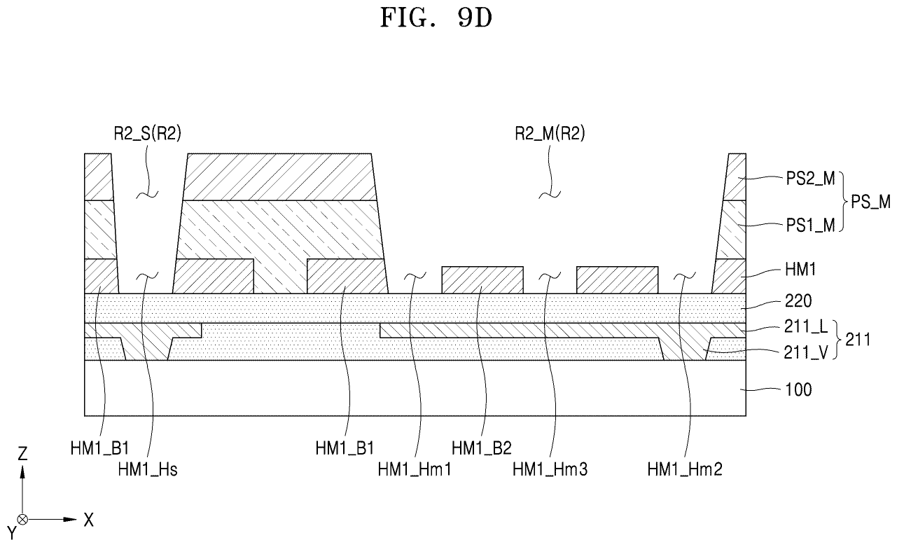

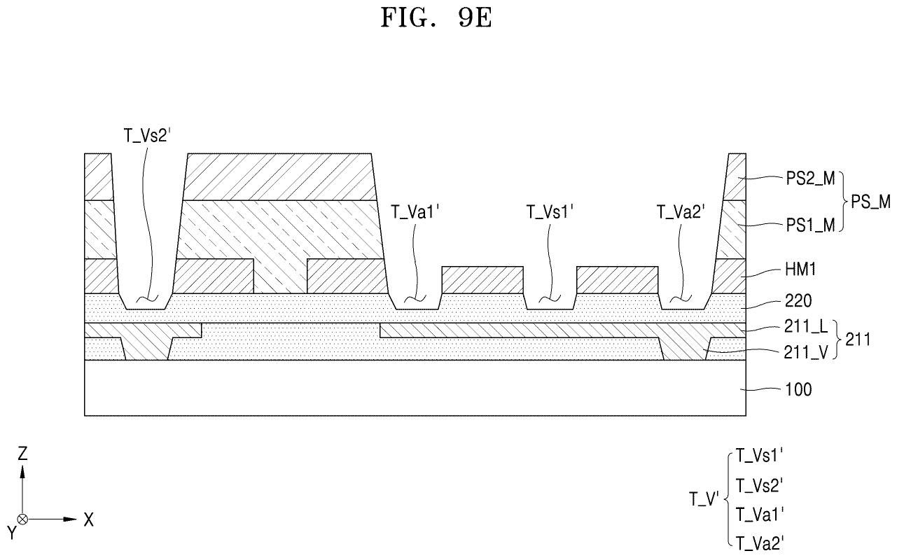

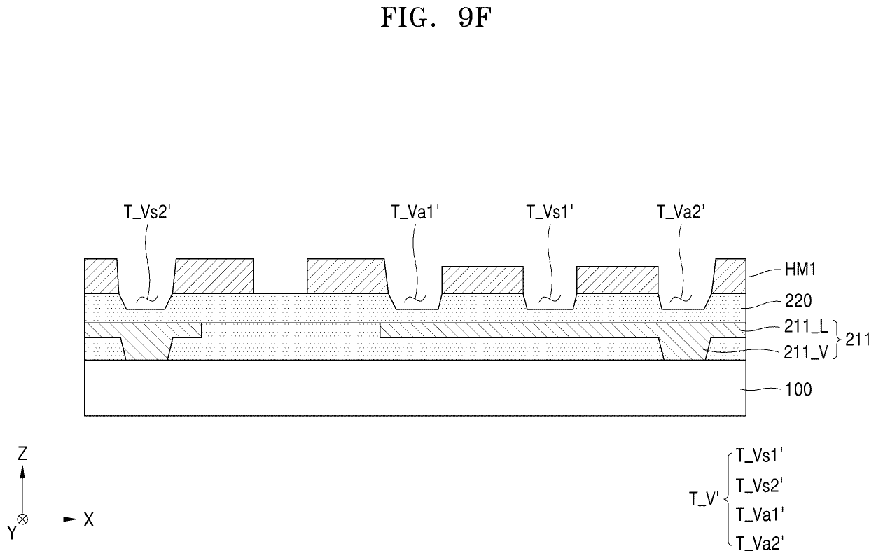

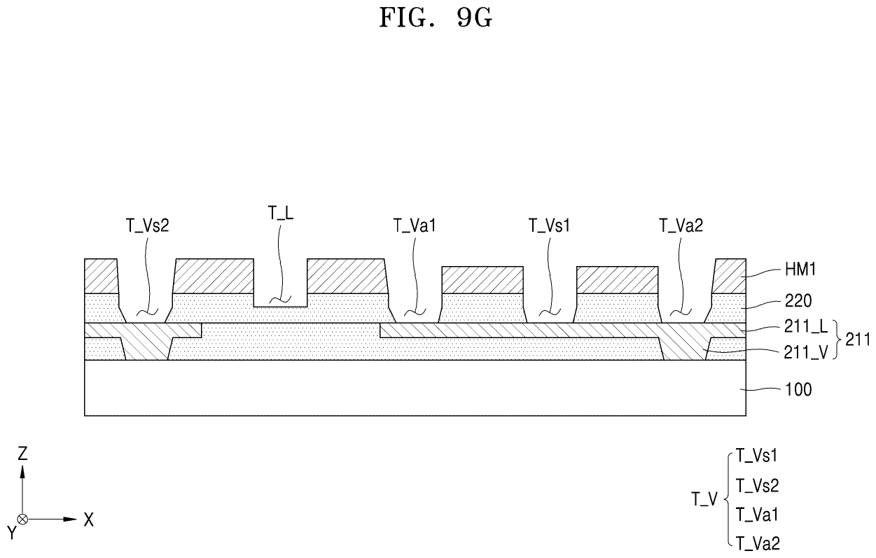

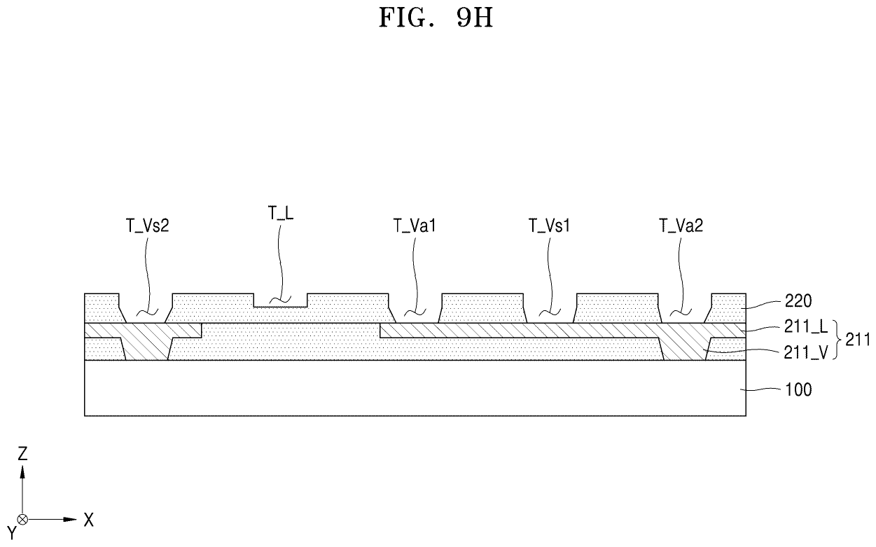

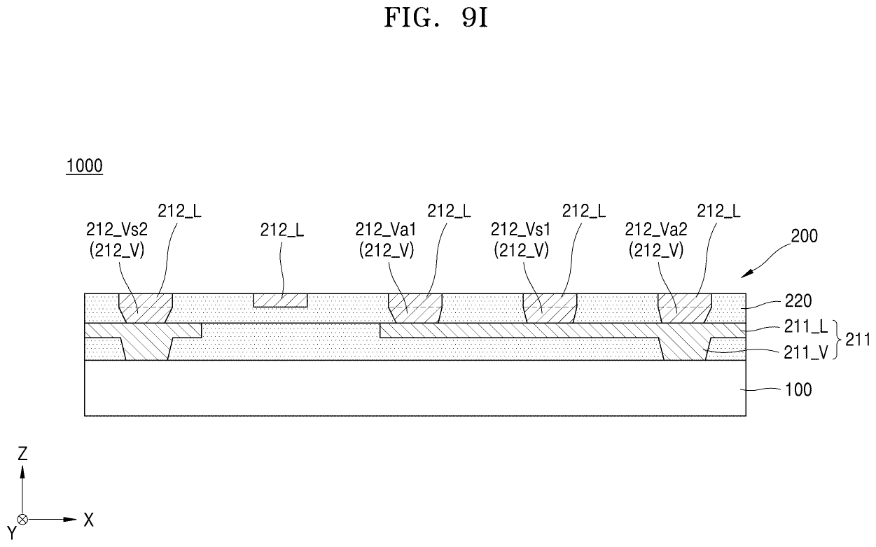

FIGS. 9A to 9I are cross-sectional views illustrating a sequential process of manufacturing the semiconductor chip 1000 according to an implementation. For example, FIGS. 9A to 9I are cross-sectional views illustrating a sequential process of manufacturing the upper layer interconnection layer 212 on the lower layer interconnection layer 211.

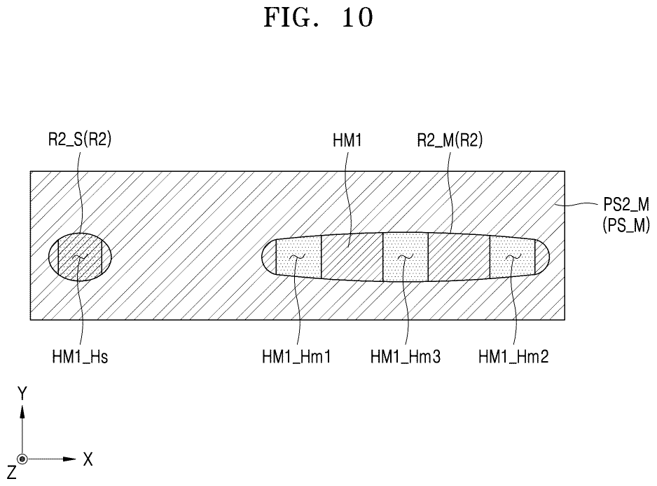

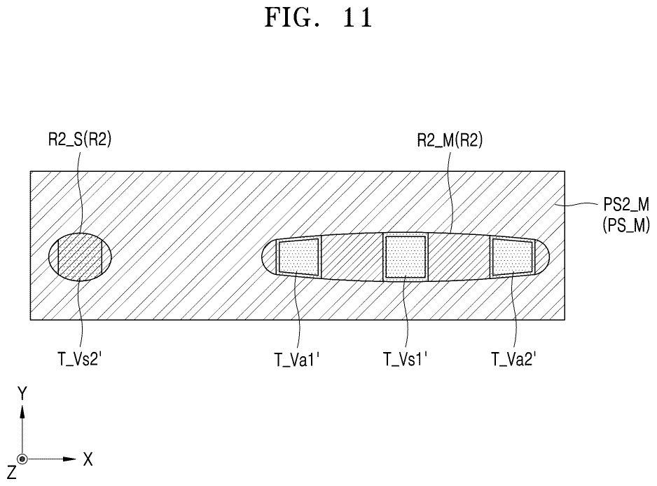

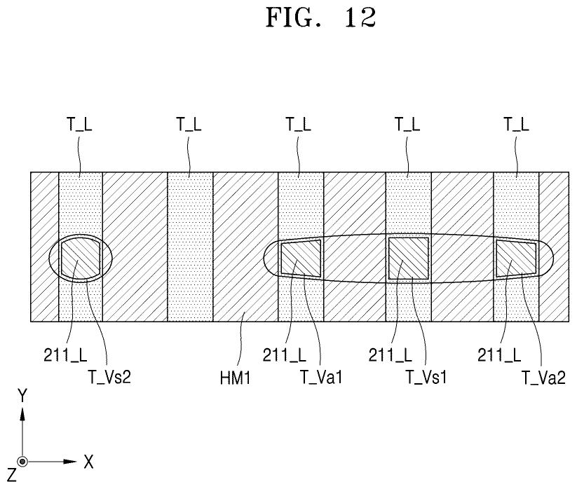

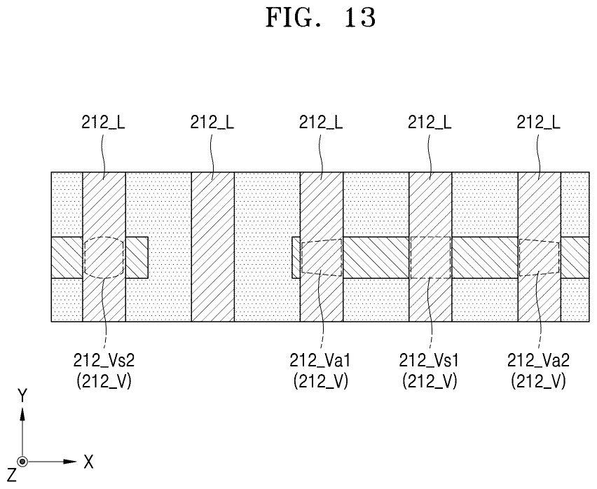

FIGS. 10 to 13 are plan views illustrating some of operations of manufacturing the semiconductor chip 1000 according to an implementation. For example, FIG. 10 is a plan view of the semiconductor chip 1000 in the operation illustrated in FIG. 9D. FIG. 11 is a plan view of the semiconductor chip 1000 in the operation illustrated in FIG. 9E. FIG. 12 is a plan view of the semiconductor chip 1000 in the operation illustrated in FIG. 9G. FIG. 13 is a plan view of the semiconductor chip 1000 in the operation illustrated in FIG. 9I.

Referring to FIG. 9A, the lower layer interconnection layer 211 and the interconnection insulating layer 220 covering the lower layer interconnection layer 211 may be formed on the semiconductor substrate 100. The lower layer interconnection layer 211 may include the plurality of lower layer interconnection lines 211_L and the plurality of lower layer interconnection vias 211_V. In FIG. 9A, the lower layer interconnection layer 211 is depicted as a first-layer interconnection layer positioned on the active surface 100_a of the semiconductor substrate 100, but the position of the lower layer interconnection layer 211 is not limited thereto.

In some implementations, an interconnection protective layer and an etch stop layer may be sequentially stacked on the upper surfaces of the plurality of lower layer interconnection lines 211_L of the lower layer interconnection layer 211. For example, an interconnection protective layer and an etch stop layer may be located between the interconnection insulating layer 220 and the upper surface of the lower layer interconnection line 211_L.

Referring to FIG. 9B, a hard mask HM1, a photo stack layer PS, and a photoresist layer PR may be formed on the interconnection insulating layer 220.

The hard mask HM1 may be positioned on the interconnection insulating layer 220 and may include a plurality of recesses HM1_H patterned to correspond to locations in which the upper layer interconnection layers 212 are to be formed later. For example, each of the plurality of recesses HM1_H may be a patterned space for the upper layer interconnection layer 212. For example, the hard mask HM1 may include tungsten (W), titanium (Ti), titanium nitride (TiN), or alloys thereof. In addition, the hard mask HM1 may include silicon nitride (SiN), silicon carbide (SiC), silicon oxide (SiO), or tetra ethyl ortho silicate (TEOS), or SiOCH.

In some implementations, the hard mask HM1 may include a plurality of layers. The hard mask HM1 including a plurality of layers may improve structural stability although widths of the plurality of recesses HM1_H are narrowed. In some implementations, the etch stop layer may be located between the hard mask HM1 and the interconnection insulating layer 220. For example, the etch stop layer may include aluminum nitride (AlN), aluminum oxide (AlO), or TEOS.

In some implementations, the plurality of recesses HM1_H may extend in the first horizontal direction (the Y direction) and be apart from each other in the second horizontal direction (the X direction). In some implementations, the hard mask HM1 may include a plurality of metal blocks HM1_B apart in the second horizontal direction (the X direction) and extending in the first horizontal direction (the Y direction) to define the plurality of recesses HM1_H.

The photo stack layer PS may be positioned on the interconnection insulating layer 220 and may fill the plurality of patterned recesses HM1_H of the hard mask HM1. For example, the hard mask HM1 may be embedded in the photo stack layer PS. For example, the photo stack layer PS may include an insulating material, such as silicon oxide or silicon nitride.

The photo stack layer PS may include a first photo stack PS1 and a second photo stack PS2. The first photo stack PS1 may be in contact with the interconnection insulating layer 220, and the hard mask HM1 may be embedded in the first photo stack PS1. The second photo stack PS2 may be positioned on the first photo stack PS1 and may be thinner than the first photo stack PS1. In some implementations, a constituent material of the first photo stack PS1 may be different from a constituent material of the second photo stack PS2.

The photoresist layer PR may be positioned on the photo stack layer PS. The photoresist layer PR may include a photosensitive resin.

Referring to FIG. 9C, a patterned photoresist layer PR_P may be formed through a photo process. Through the photo process, a first recess R1 extending from an upper surface to a lower surface of the photoresist layer PR may be formed in an region in which the plurality of upper layer interconnection vias 212_V of the upper layer interconnection layer 212 are to be formed, thereby forming the patterned photoresist layer PR_P.

Referring to FIG. 9D together with FIG. 10, a photo stack mask PS_M including a first photo stack mask PS1_M and a second photo stack mask PS2_M may be formed through an etching process.

The etching process may be performed using the patterned photoresist layer PR_P as an etching mask to form a second recess R2 extending from the upper surface to the lower surface of the photo stack layer PS, thereby forming the photo stack mask PS_M. Thereafter, the patterned photoresist layer PR_P may be removed. The second recess R2 may be formed at the bottom of the first recess R1. The first recess R1 may substantially communicate with the second recess R2.

The second recess R2 may become narrower downward in the vertical direction (the Z direction). The photo stack layer PS may include at least two photo stacks, which may facilitate forming the second recess R2 for the plurality of miniaturized upper layer interconnection vias 212_V. In addition, because the photo stack layer PS includes at least two photo stacks, even if the second recess R2 is formed in the photo stack layer PS, a phenomenon of the photo stack layer PS collapsing or breaking may be reduced.

In the process of forming the second recess R2, a portion of the hard mask HM1 may be removed. For example, in the process of manufacturing the second recess R2, a portion of part of the plurality of metal blocks HM1_B of the hard mask HM1 that is exposed externally may be removed together with the photo stack layer PS. Accordingly, in the process of manufacturing the second recess R2, the portion of the plurality of recesses HM1_H of the hard mask HM1 that is exposed externally by the second recess R2 may have a different width in the second horizontal direction (the X direction).

In some implementations, the region in which a portion of the plurality of metal blocks HM1_B is removed may be divided into a first etched region HM1_B1 and a second etched region HM1_B2. Hereinafter, side surfaces of the metal block HM1_B refer to opposite side surfaces of the metal block HM1_B that are opposite to each other in the second horizontal direction (the X direction).

The first etched region HM1_B1 may be a region in which one of side surfaces of the plurality of metal blocks HM1_B is exposed externally by the second recess R2 of one of the plurality of metal blocks HM1_B. The second etched region HM1_B2 may be a region in which all of side surfaces of the plurality of metal blocks HM1_B are exposed externally by the second recess R2 of one of the plurality of metal blocks HM1_B.

For example, in the first etched region HM1_B1 of each of the plurality of metal blocks HM1_B, the first etched side surface, which is an externally exposed side surface of each of the plurality of metal blocks HM1_B, may be inclined to have a first slope with respect to lower surfaces of the plurality of metal blocks HM1_B.

For example, in the second etched region HM1_B2 of each of the plurality of metal blocks HM1_B, the second etched side surface, which is an externally exposed side surface of each of the plurality of metal blocks HM1_B, may be inclined to have a second slope with respect to lower surfaces of the plurality of metal blocks HM1_B.

For example, in the process of manufacturing the second recess R2, the degrees of removal of the hard masks HM1 in the first etched region HM1_B1 and the second etched region HM1_B2 of the plurality of metal blocks HM1_B may be different, and thus, the first slope of the first etched side surface may be different from the second slope of the second etched side surface. For example, the first slope of the first etched side surface may be gentler than the second slope of the second etched side surface.

The second recess R2 may include a single second recess R2_S and a multi-second recess R2_M. For example, a length of the multi-second recess R2_M in the second horizontal direction (the X direction) may be greater than a length of the single second recess R2_S in the second horizontal direction (the X direction).

A portion of one of the plurality of recesses HM1_H of the hard mask HM1 may be positioned within the single second recess R2_S. For example, a portion of one recess HM1_H positioned within the single second recess R2_S may be referred to as a low-slope recess HM1_Hs. For example, the single second recess R2_S may be a space provided to form the low-slope symmetric via 212_Vs2.

The single second recess R2_S may expose one side surface of each of two adjacent metal blocks HM1_B externally. For example, in the process of manufacturing the single second recess R2_S, the space between two adjacent metal blocks HM1_B may be exposed externally.

In the process of manufacturing the single second recess R2_S, the first etched region HM1_B1 may be formed on each of the two metal blocks HM1_B exposed by the single second recess R2_S. For example, the first etched side surfaces of two adjacent metal blocks HM1_B may face each other. The low-slope recess HM1_Hs may be defined by the first etched side surfaces of two adjacent metal blocks HM1_B. In the process of manufacturing the single second recess R2_S, the first slope may be generated on each of the opposite side surfaces apart from each other in the second horizontal direction (the X direction) of the low-slope recess HM1_Hs positioned inside the single second recess R2_S.

A portion of each of at least two consecutive recesses HM1_H among the plurality of recesses HM1_H of the hard mask HM1 may be positioned within the multi-second recess R2_M. For example, the multi-second recess R2_M may be a space provided to form at least two upper layer interconnection vias 212_V that are continuous in the second horizontal direction (the X direction).

A first asymmetric recess HM1_Hm1, a second asymmetric recess HM1_Hm2, and a high-slope recess HM1_Hm3 may be positioned in succession inside the multi-second recess R2_M. For example, the high-slope recess HM1_Hm3 may be located between the first asymmetric recess HM1_Hm1 and the second asymmetric recess HM1_Hm2.

The multi-second recess R2_M may expose a continuous metal block HM1_B among the plurality of metal blocks HM1_B externally. For example, among the metal blocks HM1_B exposed externally by the multi-second recess R2_M, the end metal blocks HM1_B positioned at opposite ends in the second horizontal direction (the X direction) may have only one side surface being exposed externally and intermediate metal blocks, which are the other metal blocks, may have both side surfaces being exposed externally.

In the process of forming the multi-second recess R2_M, the first etched region HM1_B1 may be formed in each of the end metal blocks among the metal blocks HM1_B exposed externally by the multi-second recess R2_M, and the second etched region HM1_B2 may be formed in each of the intermediate metal blocks.

For example, the end metal blocks may include a first end metal block and a second end metal block apart in the second horizontal direction (the X direction). The first asymmetric recess HM1_Hm1 may be defined by the first etched side surface of the first end metal block and the second etched side surface of the intermediate metal block adjacent to the first metal block. The second asymmetric recess HM1_Hm2 may be defined by the first etched side surface of the second end metal block and the second etched side surface of the intermediate metal block adjacent to the second end metal block. The high-slope recess HM1_Hm3 may be defined by the opposite second etched side surfaces of the intermediate metal blocks adjacent to each other.

For example, one of the side surfaces of the first asymmetric recess HM1_Hm1 opposite to each other in the second horizontal direction (the X direction) may have the first slope and the other side surface may have the second slope. One of the side surfaces of the second asymmetric recess HM1_Hm2 opposite to each other in the second horizontal direction (the X direction) may have the first slope and the other side surface may have the second slope. Each of the side surfaces of the high-slope home HM1_Hm3 opposite to each other in the second horizontal direction (the X direction) may have the second slope.

Referring to FIGS. 9E and 9F together with FIG. 11, a plurality of preliminary via trenches T_V′ may be formed in the interconnection insulating layer 220 using the photo stack mask PS_M as an etching mask, and then the photo stack mask PS_M may be removed.

The plurality of preliminary via trenches T_V′ extending inward from the upper surface of the interconnection insulating layer 220 may be formed by removing a portion of the interconnection insulating layer 220 exposed by the second recess R2. For example, a plurality of preliminary via trenches T_V′ may communicate with the second recess R2. For example, the shape of each of the plurality of preliminary via trenches T_V′ may vary depending on the shape of the side surface of the metal block HM1_B positioned within the second recess R2.

For example, the plurality of preliminary via trenches T_V′ may include a preliminary low-slope trench T_Vs2′, a preliminary first asymmetric trench T_Va1′, and a preliminary second asymmetric trench T_Va2′. In some implementations, the plurality of preliminary via trenches T_V′ may further include a preliminary high-slope trench T_Vs1′ located between the preliminary first asymmetric trench T_Va1′ and the preliminary second asymmetric trench T_Va2′.

The slopes of the opposite side surfaces in the second horizontal direction (the X direction) of the preliminary low-slope trench T_Vs2′ communicating with the low-slope home HM1_Hs positioned within the single second recess R2_S may be the same as each other.

The slopes of the opposite side surfaces in the second horizontal direction (the X direction) of the preliminary first asymmetric trench T_Va1′ communicating with the first asymmetric recess HM1_Hm1 positioned within the multi-second recess R2_M may be different from each other.

The slopes of the opposite side surfaces in the second horizontal direction (the X direction) of the preliminary second asymmetric trench T_Va2′ communicating with the second asymmetric recess HM1_Hm2 positioned within the multi-second recess R2_M may be different from each other.

The slopes of the opposite side surfaces in the second horizontal direction (the X direction) of the preliminary high-slope trench T_Vs1′ communicating with the high-slope recess HM1_Hm3 positioned within the multi-second recess R2_M may be the same as each other.

In some implementations, the side surface of the low-slope recess HM1_Hs surface apart in the second horizontal direction (the X direction) may be inclined at the first slope, and the side surface of the high-slope recess HM1_Hm3 apart in the second horizontal direction (the X direction) may be inclined at the second slope that is greater than the first slope so that the slope of the side surface of the preliminary high-slope trench T_Vs1′ apart in the second horizontal direction (the X direction) may be greater than the slope of the side surface of the preliminary low-slope trench T_Vs2′ apart in the second horizontal direction (the X direction).

In some implementations, the slopes of the opposite side surfaces of the first asymmetric recess HM1_Hm1 apart in the second horizontal direction (the X direction) may be different from each other so that the slopes of the opposite side surfaces of the preliminary first asymmetric trench T_Va1′ apart in the second horizontal direction (the X direction) may be different from each other. In some implementations, the slopes of the opposite side surfaces of the second asymmetric recess HM1_Hm2 apart in the second horizontal direction (the X direction) may be different from each other so that the slopes of the opposite side surfaces of the second asymmetric trench T_Va2′ apart in the second horizontal direction (the X direction) may be different from each other.

For example, the slope of the low-slope side surface having a relatively small slope among the opposite side surfaces of the preliminary first asymmetric trench T_Va1′ apart in the second horizontal direction (the X direction) may be the same as the slope of each of the opposite side surfaces of the preliminary low-slope trench T_Vs2′ apart in the second horizontal direction (the X direction).

For example, the slope of the high-slope side surface having a relatively large slope among the opposite side surfaces of the preliminary first asymmetric trench T_Va1′ apart in the second horizontal direction (the X direction) may be the same as the slope of each of the opposite side surfaces of the preliminary high-slope trench T_Vs1′ apart in the second horizontal direction (the X direction).

Referring to FIG. 9G together with FIG. 12, a plurality of line trenches T_L may be formed in the interconnection insulating layer 220 using the hard mask HM1 as an etching mask, and then the hard mask HM1 may be removed.

Each of the plurality of line trenches T_L may extend inward from the upper surface of the interconnection insulating layer 220. The plurality of line trenches T_L may be positioned below the plurality of recesses HM1_H of the hard mask HM1 and may communicate with the plurality of recesses HM1_H, respectively. The plurality of line trenches T_L may be a space in which the plurality of upper layer interconnection lines 212_L are formed. In some implementations, the plurality of line trenches T_L may extend in the first horizontal direction (the Y direction) and may be apart from each other in the second horizontal direction (the X direction).

In the process of forming the plurality of line trenches T_L, a plurality of preliminary via trenches T_V′ may extend in the vertical direction (the Z direction) so that a plurality of via trenches T_V may be formed. For example, the plurality of via trenches T_V may be formed as the plurality of preliminary via trenches T_V′ extend to the plurality of lower layer interconnection lines 211_L, respectively. For example, a portion of the plurality of lower layer interconnection lines 211_L may be exposed through the plurality of via trenches T_V.

For example, the plurality of preliminary via trenches T_V′ may be positioned below the plurality of recesses HM1_H of the hard mask HM1 so that a bottom surface of each of the plurality of preliminary via trenches T_V′ may be exposed externally. Accordingly, in the process of etching the interconnection insulating layer 220 using the hard mask HM1 as an etching mask, the interconnection insulating layer 220 defining the bottom surface of the plurality of preliminary via trenches T_V′ may be etched together so that the plurality of preliminary via trenches T_V′ may extend so that the plurality of lower layer interconnection lines 211_L are exposed.

The plurality of via trenches T_V may include the low-slope trench T_Vs2, the first asymmetric trench T_Va1, and the second asymmetric trench T_Va2. In some implementations, the plurality of via trenches T_V may further include a high-slope trench T_Vs1 located between the first asymmetric trench T_Va1 and the second asymmetric trench T_Va2.

The low-slope trench T_Vs2 may be formed as the preliminary low-slope trench T_Vs2′ further extends in the vertical direction (the Z direction). The first asymmetric trench T_Va1 may be formed as the preliminary first asymmetric trench T_Va1′ further extends in the vertical direction (the Z direction). The second asymmetric trench T_Va2 may be formed as the preliminary second asymmetric trench T_Va2′ further extends in the vertical direction (the Z direction). The high-slope trench T_Vs1 may be formed as the preliminary high-slope trench T_Vs1′ further extends in the vertical direction (the Z direction).

The slopes of the opposite side surfaces of the low-slope trench T_Vs2 in the second horizontal direction (the X direction) may be the same. The slopes of the opposite side surfaces of the first asymmetric trench T_Va1 in the second horizontal direction (the X direction) may be different. The slopes of the opposite side surfaces of the second asymmetric trench T_Va2 in the second horizontal direction (the X direction) may be different. The slopes of the opposite side surfaces of the high-slope trench T_Vs1 in the second horizontal direction (the X direction) may be the same.

In some implementations, the slope of the side surface of the high-slope trench T_Vs1 apart in the second horizontal direction (the X direction) may be greater than the slope of the side surface of the low-slope trench T_Vs2 apart in the second horizontal direction (the X direction).

In some implementations, the slope of the low-slope side surface having a relatively small slope among the opposite side surfaces of the first asymmetric trench T_Va1 apart in the second horizontal direction (the X direction) may be the same as the slope of each of the opposite side surfaces of the low-slope trench T_Vs2 apart in the second horizontal direction (the X direction).

In some implementations, the slope of the high-slope side surface having a relatively large slope among the opposite side surfaces of the first asymmetric trench T_Va1 apart in the second horizontal direction (the X direction) may be the same as the slope of each of the opposite side surfaces of the high-slope trench T_Vs1 apart in the second horizontal direction (the X direction).

Referring to FIGS. 9H and 9I together with FIG. 13, after the hard mask HM1 is removed, the upper layer interconnection layer 212 may be formed in the plurality of line trenches T_L and the plurality of via trenches T_V.

In some implementations, after forming the upper layer seed layer (212_S, see FIG. 4) through a sputtering process in the plurality of via trenches T_V and the plurality of line trenches T_L, the plurality of via trenches T_V and the plurality of line trenches T_L may be filled with a conductive material through an electroplating process. For example, the upper layer seed layer may include a barrier metal layer and a liner layer.

For example, the plurality of upper layer interconnection vias 212_V may be formed at the bottom of the plurality of via trenches T_V, respectively, and the plurality of upper layer interconnection lines 212_L may be formed at the top of the plurality of via trenches T_V, respectively. The plurality of upper layer interconnection vias 212_V and the plurality of upper layer interconnection lines 212_L formed inside the plurality of via trenches T_V may form an integral body. The upper layer interconnection layer 212 may be electrically connected to the lower layer interconnection layer 211 through the plurality of upper interconnection vias 212_V.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A semiconductor chip comprising:
a semiconductor substrate; and
an interconnection structure on the semiconductor substrate, the interconnection structure including a plurality of interconnection layers and a plurality of interconnection insulating layers, each of the plurality of interconnection layers including a plurality of interconnection lines and a plurality of interconnection vias, and the plurality of interconnection insulating layers correspondingly surrounding the plurality of interconnection layers,
wherein the plurality of interconnection layers include an upper layer interconnection layer, the upper layer interconnection layer including a plurality of upper layer interconnection lines, the plurality of upper layer interconnection lines extending in a first horizontal direction and being apart from each other in a second horizontal direction perpendicular to the first horizontal direction, and
wherein the upper layer interconnection layer includes a plurality of upper layer interconnection vias, the plurality of upper layer interconnection vias including at least one upper layer asymmetric via, and wherein each of the at least one upper layer asymmetric via comprises a first side surface and a second side surface that are opposite to each other in the second horizontal direction and have different slopes.

2. The semiconductor chip of claim 1, wherein
the plurality of upper layer interconnection vias include a first upper layer asymmetric via and a second upper layer asymmetric via, and
the first upper layer asymmetric via and the second upper layer asymmetric via are arranged in a straight line in the second horizontal direction.

3. The semiconductor chip of claim 2, wherein
the plurality of upper layer interconnection lines include a first upper layer interconnection line and a second upper layer interconnection line that are adjacent to each other,
the first upper layer interconnection line is connected to the first upper layer asymmetric via, and
the second upper layer interconnection line is connected to the second upper layer asymmetric via.

4. The semiconductor chip of claim 2, wherein
the first side surface of the first upper layer asymmetric via includes a first high-slope side surface, and the second side surface of the first upper layer asymmetric via includes a first low-slope side surface,
the first side surface of the second upper layer asymmetric via includes a second high-slope side surface, and the second side surface of the second upper layer asymmetric via includes a second low-slope side surface, and
the first high-slope side surface of the first upper layer asymmetric via faces the second high-slope side surface of the second upper layer asymmetric via.

5. The semiconductor chip of claim 2, wherein
the plurality of upper layer interconnection vias include a high-slope symmetric via, the high-slope symmetric via comprising a first side surface and a second side surface that are opposite to each other in the second horizontal direction and have a same slope, and
the high-slope symmetric via is between the first upper layer asymmetric via and the second upper layer asymmetric via in the second horizontal direction, and the high-slope symmetric via is apart from the first upper layer asymmetric via and the second upper layer asymmetric via in the second horizontal direction.

6. The semiconductor chip of claim 5, wherein
the plurality of upper layer interconnection lines include a first upper layer interconnection line connected to the first upper layer asymmetric via, a second upper layer interconnection line connected to the second upper layer asymmetric via, and a third upper layer interconnection line connected to the high-slope symmetric via, and
the third upper layer interconnection line is between the first upper layer interconnection line and the second upper layer interconnection line.

7. The semiconductor chip of claim 5, wherein
the first side surface of the first upper layer asymmetric via includes a first high-slope side surface, and the second side surface of the first upper layer asymmetric via includes a first low-slope side surface,
the first side surface of the second upper layer asymmetric via includes a second high-slope side surface, and the second side surface of the second upper layer asymmetric via includes a second low-slope side surface,
a slope of each of the first and second side surfaces of the high-slope symmetric via is a same as a slope of the first high-slope side surface, and
each of the first high-slope side surface and the second high-slope side surface faces a respective side surface of the first and second side surfaces of the high-slope symmetric via.

8. The semiconductor chip of claim 1, wherein
the plurality of upper layer interconnection vias include a low-slope symmetric via, the low-slope symmetric via comprising a first side surface and a second side surface that are opposite to each other in the second horizontal direction and have a same slope,
the first side surface of each of the at least one upper layer asymmetric via comprises a low-slope side surface, and
a slope of each of the first and second side surfaces of the low-slope symmetric via is a same as a slope of the low-slope side surface.

9. The semiconductor chip of claim 1, wherein a number of the at least one upper layer asymmetric via is an even number.

10. The semiconductor chip of claim 1, wherein
the plurality of upper layer interconnection vias extend downward in a vertical direction respectively from lower surfaces of the plurality of upper layer interconnection lines, and
a width of each of the plurality of upper layer interconnection vias decreases away from the plurality of upper layer interconnection lines.

11. A semiconductor chip comprising:
a semiconductor substrate; and
an interconnection structure on the semiconductor substrate, the interconnection structure including a plurality of interconnection layers and a plurality of interconnection insulating layers, each of the plurality of interconnection layers including a plurality of interconnection lines and a plurality of interconnection vias, the plurality of interconnection insulating layers correspondingly surrounding the plurality of interconnection layers,
wherein the plurality of interconnection layers include a lower layer interconnection layer and an upper layer interconnection layer, the upper layer interconnection layer being on the lower layer interconnection layer,
wherein the lower layer interconnection layer includes a plurality of lower layer interconnection lines extending in a second horizontal direction, the plurality of lower layer interconnection lines being apart from each other in a first horizontal direction perpendicular to the second horizontal direction,
wherein the upper layer interconnection layer includes a plurality of upper layer interconnection lines extending in the first horizontal direction, the plurality of upper layer interconnection lines being apart from each other in the second horizontal direction, the upper layer interconnection layer including a plurality of upper layer interconnection vias correspondingly connecting the plurality of upper layer interconnection lines to the plurality of lower layer interconnection lines, a width of each of the plurality of upper layer interconnection vias decreasing toward the plurality of lower layer interconnection lines, and
wherein the plurality of upper layer interconnection vias include at least one upper layer asymmetric via, each of the at least one upper layer asymmetric via comprises a first side surface and a second side surface that are opposite to each other in the second horizontal direction and have different slopes.

12. The semiconductor chip of claim 11, wherein
the plurality of upper layer interconnection lines include a first upper layer interconnection line and a second upper layer interconnection line adjacent to each other,
the at least one upper layer asymmetric via includes:
a first upper layer asymmetric via, the first side surface of the first upper layer asymmetric via including a first high-slope side surface, and the second side surface of the first upper layer asymmetric via including a first low-slope side surface, the first upper layer asymmetric via contacting the first upper layer interconnection line; and
a second upper layer asymmetric via, the first side surface of the second upper layer asymmetric via including a second high-slope side surface, and the second side surface of the second upper layer asymmetric via including a second low-slope side surface, the second upper layer asymmetric via contacting the second upper layer interconnection line,
the first upper layer asymmetric via and the second upper layer asymmetric via are arranged in a straight line in the second horizontal direction, and
the first high-slope side surface of the first upper layer asymmetric via faces the second high-slope side surface of the second upper layer asymmetric via.

13. The semiconductor chip of claim 12, wherein
the plurality of lower layer interconnection lines include a first lower layer interconnection line, the first lower layer interconnection line including a first lower layer interconnection block and a second lower layer interconnection block, the first lower layer interconnection block and the second lower layer interconnection block extending in the second horizontal direction and being apart from each other in the second horizontal direction,
the first upper layer asymmetric via is in contact with the first lower layer interconnection block, and
the second upper layer asymmetric via is in contact with the second lower layer interconnection block.

14. The semiconductor chip of claim 12, wherein
the plurality of lower layer interconnection lines include a first lower layer interconnection line, the first lower layer interconnection line including a plurality of lower layer interconnection blocks, the plurality of lower layer interconnection blocks extending in the second horizontal direction and being apart from each other in the second horizontal direction, and
the first upper layer asymmetric via and the second upper layer asymmetric via are both connected to a lower layer interconnection block of the plurality of lower layer interconnection blocks.

15. The semiconductor chip of claim 11, wherein
the plurality of upper layer interconnection lines include a first upper layer interconnection line, a second upper layer interconnection line, and a third upper layer interconnection line,
the third upper layer interconnection line is between the first upper layer interconnection line and the second upper layer interconnection line,
the plurality of upper layer interconnection vias include a first upper layer asymmetric via contacting the first upper layer interconnection line, a second upper layer asymmetric via contacting the second upper layer interconnection line, and a high-slope symmetric via contacting the third upper layer interconnection line, the high-slope symmetric via having a first side surface and a second side surface that are opposite to each other in the second horizontal direction and have a same slope, and
the first upper layer asymmetric via, the second upper layer asymmetric via, and the high-slope symmetric via are arranged in a straight line in the second horizontal direction.

16. The semiconductor chip of claim 15, wherein
the plurality of lower layer interconnection lines include a first lower layer interconnection line, the first lower layer interconnection line including a plurality of lower layer interconnection blocks extending in the second horizontal direction and being apart from each other in the second horizontal direction,
the plurality of lower layer interconnection blocks include a first lower layer interconnection block in contact with the first upper layer asymmetric via, a second lower layer interconnection block in contact with the second upper layer asymmetric via, and a third lower layer interconnection block in contact with the high-slope symmetric via, and
the third lower layer interconnection block is between the first lower layer interconnection block and the second lower layer interconnection block.

17. The semiconductor chip of claim 15, wherein
the plurality of upper layer interconnection vias include a low-slope symmetric via, the low-slope symmetric via having a first side surface and a second side surface that are opposite to each other in the second horizontal direction and have a same slope, and
a slope of the first side surface of the high-slope symmetric via is greater than a slope of the first side surface of the low-slope symmetric via.

18. The semiconductor chip of claim 12, wherein a number of the at least one upper layer asymmetric via is an even number.

19. A semiconductor chip comprising:
a semiconductor substrate; and
an interconnection structure on the semiconductor substrate, the interconnection structure including a plurality of interconnection layers and a plurality of interconnection insulating layers, each of the plurality of interconnection layers including a plurality of interconnection lines and a plurality of interconnection vias, the plurality of interconnection insulating layers correspondingly surrounding the plurality of interconnection layers,
wherein the plurality of interconnection layers include an upper layer interconnection layer, the upper layer interconnection layer including a plurality of upper layer interconnection lines, the plurality of upper layer interconnection lines extending in a first horizontal direction and being apart from each other in a second horizontal direction perpendicular to the first horizontal direction, and
wherein the upper layer interconnection layer includes a plurality of upper interconnection vias, the plurality of upper interconnection vias including a plurality of upper layer asymmetric vias and at least one symmetric via, each of the plurality of upper layer asymmetric vias including a first side surface and a second side surface that are opposite to each other in the second horizontal direction and have different slopes, each of the at least one symmetric via including a first side surface and a second side surface that are opposite to each other in the second horizontal direction and have a same slope,
wherein a number of the plurality of upper layer asymmetric vias is an even number,
wherein the plurality of upper layer asymmetric vias include a pair of upper layer asymmetric vias, the pair of upper layer asymmetric vias being arranged in a straight line in the second horizontal direction, and
wherein a high-slope side surface of a first upper layer asymmetric via of the pair of upper layer asymmetric vias faces a high-slope side surface of a second upper layer asymmetric via of the pair of upper layer asymmetric vias.

20. The semiconductor chip of claim 19, wherein
the at least one symmetric via includes a low-slope symmetric via and a high-slope symmetric via, the high-slope symmetric via having a side surface that has a greater slope than a side surface of the low-slope symmetric via,
the high-slope symmetric via is between the pair of upper layer asymmetric vias, and the high-slope symmetric via and the pair of upper layer asymmetric vias are arranged in a straight line in the second horizontal direction, and
a space between the pair of upper layer asymmetric vias is free of the low-slope symmetric via, or the low-slope symmetric via is positioned away from the straight line.
